(19) United States
(12) Patent Application Publication
(10) Pub. No.: US 2026/0142118 A1
(43) Pub. Date: May 21, 2026

(54) ULTRA FAST PULSER FOR LOW ENERGY ELECTRON BEAMS

(71) Applicant: Euclid Techlabs, LLC, Solon, OH (US)

(72) Inventors: Chunguang Jing, Naperville, IL (US); Eric John Montgomery, Oak Park, IL (US); Yubin Zhao, Naperville, IL (US); Bartosz Wyderski, Franklin Park, IL (US); Sean Miller, Freeport, IL (US); Wade Rush, Lawrence, KS (US); Roman Kostin, Oak Park, IL (US); Alexei Kanareykin, Bethesda, MD (US)

(73) Assignee: Euclid Techlabs, LLC, Solon, OH (US)

(21) Appl. No.: 19/393,856

(22) Filed: Nov. 19, 2025

Related U.S. Application Data
(60) Provisional application No. 63/722,926, filed on Nov. 20, 2024.

(51) Int. Cl. H01J 37/04; H01J 37/06; H01J 37/26; H01J 37/28

(52) U.S. Cl. CPC H01J 37/045; H01J 37/06; H01J 37/265; H01J 37/28; H01J 2237/0432; H01J 2237/0455; H01J 2237/083; H01J 2237/1504

(57) ABSTRACT

An electron beam pulser suitable for SEM systems directs ≤30 keV electrons through a stripline kicker. RF waves or voltage pulses deflect the beam to periodically impinge on an aperture, thereby creating electron pulses from 100 fs to 100 ns in width. In RF embodiments, the RF frequency is tuned to provide 180-degree phase slippage between the RF and the electron beam, thereby generating pulse repetition rates up to 20 GHz without divergence. The RF can be reverse propagated through the kicker to reduce kicker size and/or increase the maximum pulse repetition rate. Voltage pulse embodiments provide flexible pulse widths and timing with repetition rates up to 1 GHz. A DC bias is applied to enable electron transit only during the voltage pulses, or offset voltage pulses of opposite sign can produce narrow electron pulses only during voltage pulse overlap. The EMMP can be synchronized for pump-probe experiments.

### RELATED APPLICATIONS

This application claims the benefit of U.S. Provisional Application No. 63/722,926, filed Nov. 20, 2024, which is herein incorporated by reference in its entirety for all purposes. This application is also related to U.S. Pat. No. 9,697,982, issued on Jul. 4, 2017, U.S. Pat. No. 10,319,556 issued Jun. 11, 2019, U.S. Pat. No. 10,515,733 issued Dec. 24, 2019, and U.S. Pat. No. 10,804,001 issued Oct. 13, 2020. All of these applications are herein incorporated by reference in their entirety for all purposes.

### FIELD OF THE INVENTION

The invention relates to apparatus and methods for generating pulsed electron beams, and more particularly, to apparatus and methods for generating and controlling pulsed electron beams that are applicable to scanning electron microscopy.

### BACKGROUND OF THE INVENTION

Generation and precise control of pulsed electron beams is required for many industrial, medical, and research applications, including scanning electron microscopy (SEM), transmission electron microscopy (TEM), and horizontal/vertical accelerator-based beamlines (HAB/VAB), as well as relevant experimental analytical methods that use electron beams in SEM or TEM, or in HAB/VAB as probes.

In research, pulsed electron beams with ultrashort pulse durations are used for studying a variety of materials. Frequently, when investigating dynamic processes, the electron beams are combined with other primary excitation probes such as laser beams or other photon-based probes such as X-ray beams. An example would be the “pump-probe” class of experiments. In order to achieve pump-probe time-resolved imaging, the electron pulses must be synchronized (with jitter substantially lower than the pulse duration) to the pump device. According to one approach, sometimes referred to as “ultrafast pump-probe SEM” (also termed SUEM) a laser pump is used to excite the electrons and create the beam. The pulse widths of the laser pump can be as short as 50 femtoseconds or less, which can produce beams with pulse durations of less than one-nanosecond or even less than one picosecond. However, the pulse repetition rate in a pump-probe system is generally quite low, typically less than 100 MHz. Furthermore, frequent and tedious alignment of the drive laser beam with the electron emitter is required. The emitter tip can be flattened to enhance the emission area and total beam current, but this degrades the effective source size and ability to sharply focus the beam probe, thereby limiting spatial resolution.

Another approach for generating pulsed electron beams that avoids using lasers is to mechanically or electromagnetically block and unblock (i.e. “chop”) a continuous electron beam at a desired periodicity, according to the desired electron pulse timing. According to this approach, a continuous beam of electrons is directed through a device, referred to herein as an electro-magnetic mechanical pulser (EMMP), that operates to chop the beam and collimate the output. The EMMP includes a “kicker” that uses radio frequency energy to impose a transverse spatial oscillation onto the beam according to at least one of a time-varying electric field and a time-varying magnetic field generated within the kicker, after which a “chopping, collimating aperture” (CCA) is used to chop the oscillating beam into pulses. Approaches have been demonstrated that use this deflecting approach for chopping electron beams of between 10 keV up to 300 keV and higher at pulse repetition rates greater than 1 GHz.

FIG. 1A is a conceptual diagram that illustrates the fundamental concepts underlying the EMMP approach. In the illustrated example, an initially continuous, “DC” electron beam 100 is transversely modulated into a sinusoid 110 as it passes through a vacuum-filled kicker 102 that imposes a sinusoidal transverse spatial oscillation 110 onto the beam. The amplitude of the sinusoid 110 grows as the beam propagates, and then the beam 110 impinges upon a chopping, collimating aperture, or “CCA” 104, having an aperture 106. The CCA “chops” the beam into pulses 108 that emerge from the CCA at a repetition rate that is twice the kicker modulation rate, because the pulses 108 are produced by cutting the sinusoid 110 of the beam modulation on both the up-swing and the down-swing. The aperture 106 of the CCA 104 and the modulating field of the kicker 102 work together to tune the pulse lengths of the resulting pulsed beam 108.

After the beam 100 has been chopped into pulses 108, if nothing further were done, both the longitudinal and lateral divergence of the stream of pulses 108 would increase. In other words, the pulses would get longer (temporal divergence in the propagation or “z” direction) and would spread out (spatial dispersion in the x and y directions). So as to avoid this, as shown in FIG. 1A, additional components 112, 114 are included in a divergence suppressing section downstream of the CCA 110 that reverses and suppresses this divergence. In the example of FIG. 1A, the divergence suppressing section includes an additional, demodulating kicker 114, which is identical in design to the modulating kicker 102, as well as a magnetic quadrupole 112.

FIG. 1B illustrates a pulser system 120 that includes the components of FIG. 1A, where the divergence suppressing section further includes two additional magnetic quadrupoles 116, 118.

One possibility for implementing an EMMP kicker is to deflect the electron beam using electromagnetic coil deflectors. However, this approach suffers from large inductance, limiting the probe beam scan speed (i.e. the settling time of a change in the coil drive current) to greater than 1 microsecond

Another possibility for implementing an EMMP kicker is to use a “stripline,” such as a metallic traveling wave stripline, which in its simplest form comprises two flat metallic parallel slabs. However, even for high energy electron beams from 30 keV to 1 MeV and higher, the electrons travel at speeds that are well below the velocity of light. For example, in TEM applications the energy of the electrons is typically in the range of 100 keV to 300 keV, whereby the electron beam speed is around 2.1×10⁸ m/s, which is only about 70% of the speed of light. Accordingly, as the electrons traverse a traveling wave stripline, there is a phase “slippage” between the RF and the electrons that arises from the difference between the electron velocity Ve and the phase velocity of the RF, which is the speed of light if the medium between two slabs is vacuum or air, causing the overall applied kicking force to be greatly reduced, or even cancelled.

The present Applicant has introduced several approaches that can eliminate phase slippage for higher energy electron beams, i.e. for beam energies above 30 keV. One of these approaches is disclosed, for example, in U.S. Pat. No. 9,697,982, and in an article published in Ultramicroscopy 161 (2016 ) 130-136, both of which are incorporated herein by reference in their entirety for all purposes. This approach replaces the stripline with a resonant cavity, also referred to herein as a “transverse deflection cavity” TDC, and generates standing EMF waves within the TDC-EMMP cavity by applying RF at a primary resonant frequency of the cavity. Phase slippage is eliminated by this approach, because the phase velocity of the RF standing waves in the resonant cavity is zero. However, this approach limits the RF frequency, and hence the deflection frequency of the electron beam, to only one frequency, or at most to a few discrete frequencies.

Another approach introduced by the present Applicant for avoiding phase slippage is directed to higher energy electron beams, as are typical for example in TEM system. This approach implements a traveling RF wave in a stripline that is configured to reduce the phase velocity of the RF as it propagates through the kicker, so that it is matched to the electron velocity, thereby eliminating phase slippage. U.S. Pat. No. 10,319,556, included herein by reference in its entirety for all purposes, discloses an approach wherein the RF wave is propagated through a Traveling Wave Transmission Stripline (TWTS) containing a dielectric, thereby causing the phase velocity of the RF wave to be slower than the speed of light, and thereby allowing the electron velocity to be matched to the RF phase velocity.

A similar approach, also introduced by the present Applicant and disclosed for example in U.S. Pat. Nos. 10,515,733 and 10,804,001, is to provide a “Traveling Wave Metallic Comb Stripline” kicker (“TWMCS”), also referred to herein as a TWMCS-EMMP, as an alternative to the TWTS-EMMP. The TWMCS-EMMP includes at least one pair of opposing combs, and in embodiments two orthogonal pair of opposing combs, which serve to reduce the phase velocity of the RF in the EMMP. The RF phase velocity in these TWTS and TWMCS approaches is independent of the RF frequency, such that the modulation rate of the beam and the resulting pulse rate can be tuned over a very wide range by adjusting the RF frequency to a desired value. Independently, the amplitude of the electron beam modulation, and thereby the pulse width, and consequently the pulse duty cycle, can be varied by varying the amplitude of the applied RF.

However, these phase velocity matching solutions are applicable only to higher energy beams having energies above 60 keV, because it is impractical or impossible to further reduce the phase velocity of the RF.

Dosing a sample with probe electrons that meet, but do not exceed, a required energy is a challenge long appreciated in SEM. If the electron beam is too intense, or the time-integrated dose is too great, then the microscopist risks altering the observed object. Imaging radiation-sensitive matter requires a deep understanding of electron-beam-induced sample evolution. In biosciences, for example, beam-induced specimen damage is addressed by limiting the accumulated electron dose during cryogenic electron microscopy (cryo-EM). In SEM, measures to reduce the electron beam damage apply different scanning strategies, including reduced exposure times at a given probing spot, specifically defined probing patterns, sparse probing spots, and applying advanced algorithms to image reconstruction, among others.

Moreover, time-resolved electron microscopy (4D-EM) has arisen in the last decade, which stimulates interest in studying dynamic processes that lead to functional behavior. In such cases, beam-sample interactions must be limited to very short durations. Recent work on dose fractionation has emphasized control of the rate of single-electron interaction events with the illuminated area at very low dose rates as a method to explore material response. For SEM of sensitive materials, including critical dimension SEM (CD-SEM) of extreme ultraviolet (EUV) photoresists in industrial settings, it would be attractive to have a widely variable time-structured dosing methodology, extending to ultrashort pulse durations at wide pulse-to-pulse temporal spacing.

However, for electron energies near or below 30 keV, as is often the case for SEM systems, when it is desirable to vary the RF frequency, and thereby vary the pulsing rate, it can be impossible to avoid phase slippage in a stripline EMMP. One approach is to implement capacitive deflector plates as the kicker, thereby minimizing the interaction time between the electron beam and the kicker, and minimizing the phase slippage. However, this approach can typically achieve time resolutions of no better than 90 ps. Perhaps even more importantly, these approaches typically result in very extensive electron beam quality deterioration in both the transverse direction (beam diameter and divergence) and longitudinal direction (temporal coherence), which must be compensated by additional downstream focusing devices, such as quadrupoles or “mirror” kickers, which can be complex and expensive, and which can exceed space availability and thereby preclude retrofit of existing SEM designs.

What is needed, therefore, is an ultrafast electrostatic EMMP deflector that is capable of deflecting electron beams having energies from 1-30 keV to produce pulsed electron beams having pulse repetition rates of up to 20 GHz with electron pulse widths below 10 ps with little if any divergence, thereby enabling retrofit to existing SEM designs.

### SUMMARY OF THE INVENTION

The present invention is an ultrafast electrostatic EMMP deflector that is capable of deflecting electron beams having energies from 1-30 keV to produce pulsed electron beams having pulse repetition rates up to 20 GHz with electron pulse widths below 10 ps, and in embodiments below 1 ps, with little if any divergence.

In embodiments, the disclosed electrostatic deflector, also referred to as a “low energy stripline” or LES kicker, is a single compact module that is can be included in an SEM column, thereby enabling retrofit to existing SEM designs. In various embodiments, pump-probe time-resolved imaging is enabled by synchronizing the EMMP deflector (with jitter substantially lower than the pulse duration) to a pump device.

According to the present disclosure, the stripline of the LES kicker includes a termination impedance (such as 50 ohms) that matches the impendence of the stripline, thereby providing an ultra-high bandwidth stripline that can propagate pure traveling wave electromagnetic energy over a frequency range from DC to nearly 12 GHz, which corresponds to better than 100 ps rise time. In embodiments, the LES kicker comprises two flat metallic parallel slabs, at least one of which is fed by an electromagnetic energy input, such as a coaxial port. Various embodiments provide for the electromagnetic energy to travel through the stripline in the same direction as the electrons (forward propagation), or in the opposite direction (reverse propagation). The CCA (if included) 104 can have an aperture of between 1 mm and 70 micrometers.

Rather than attempting to avoid RF phase slipping or limiting the interaction time between the electrons and RF traveling through the LES kicker, the disclosed invention implements either of two alternatives. In the first approach, referred to herein as RF LES, radio frequency energy is applied to the LES. In embodiments, RF is applied to both slabs of the stripline with signals having a relative phase difference of 180 degrees (differential input). According to this approach, the frequency of the RF is tuned such that the total phase slippage during transit of each electron is 180 degrees. When an electron enters the LES, the electron will be deflected, and will not pass through the CCA, unless it enters when the RF voltage is at its minimum (or maximum) value, in which case the electron will exit the LES with pure displacement and near-zero divergence from the desired optical path, and will pass through the CCA. Accordingly, the electrons that pass through the CCA and contribute to the pulsed output beam are displaced but have negligible transverse momentum, such that the divergence of the output beam is minimized or eliminated. As a result, in embodiments it is not necessary to include downstream dispersion-compensating elements, as is required in the prior art (FIG. 1A).

According to the RF LES approach, the required RF frequency is determined by the electron beam energy and the length of the stripline. Embodiments employ feedback circuits that stabilize and maintain the phase slippage at 180 degrees. In embodiments, a moveable CCA is implemented, thereby enabling the position of the aperture to be precisely placed in a location where only the displaced beam with substantially no transverse momentum can pass through, thereby allowing a tolerance of about ±30°, limited by inefficiency of displacement as we move off the optimum 180°.

In embodiments, the divergence of the output beam is further reduced by implementing a double aperture to allow only the displaced beam having zero transverse momentum, i.e. zero divergence, to pass through, while blocking other beams, such as the return-swept beam, that have nonzero transverse momentum and divergence.

In some embodiments, the RF is “forward propagated” through the LES, i.e. applied in a direction that is the same as the electron beam direction. In other embodiments, the RF is “reverse propagated” through the LES, i.e. applied in a direction that is opposite to the electron beam, thereby increasing the phase slippage per unit length of the LES. This reverse propagation approach enables the length of the LES to be reduced as compared to a forward propagating slippage scheme, thereby making the LES EMMP more compact for a given beam energy and RF frequency, and/or increases the RF frequency, and therefore the pulse repetition rate, for a given beam energy and LES length.

In various RF LES embodiments, pulse repetition rates of up to 20 GHz can be achieved.

According to the second approach, referred to herein as Pulse LES or PLES, the LES is driven by a series of unipolar, substantially square voltage pulses produced by a voltage pulser. With proper PLES impedance matching, settling times of less than 80 ps between the on and off states of the voltage pulses in the PLES can be achieved, corresponding to electron pulse durations (width) of less than 10 ps, with up to 400 MHz pulse repetition frequency.

In embodiments, voltage pulses are directed to one of the slabs of the PLES, which is impedance matched, while a DC bias that is equal and opposite to the maximum amplitude of the voltage pulses is applied to the other slab of the PLES. As a result, electrons in the beam are deflected and do not pass through the CCA, except during the voltage pulses, when the net field in the PLES is zero. Accordingly, the electron pulse widths and pulse repetition rates of the output beam are independent of the beam energy, and are determined solely by the lengths and repetition rate of the voltage pulses. In some embodiments, the disclosed PLES EMMP does not include a CCA, and cutoff of deflected beams is achieved instead at existing downstream microscope apertures. In other embodiments, a CCA is included to ensure collimation of the beam, and to block the beam between the voltage pulses. The CCA aperture can also serve to block the beam except during the rise and fall times of the voltage pulses, if for example the applied DC bias is set to half the voltage pulse amplitude, thereby substantially shortening the durations of the electron beam pulses.

Unlike RF energy, which transitions sinusoidally between positive and negative voltages, the voltage pulses alternate between a maximum amplitude and zero. The only “phase slippage” and beam divergence that arises in PLES embodiments occurs during the rising and falling edges of the voltage pulses. For this reason, the electron deflection efficiency is beam-energy-dependent at the rising or falling edges of the voltage pulses. However, these rising and falling edges can be minimized by reverse propagation of the voltage pulses through the PLES.

Accordingly, PLES embodiments allow virtually any desired combination of beam energy, electron pulse width, and electron pulse repetition rate. This is particularly important for critical-dimension SEM in chip fabs, which usually operate at beam energies well below 30 keV. In various PLES embodiments, pulse repetition rates of up to 1 GHz can be achieved.

In some embodiments, pump-probe stroboscopic imaging can be performed using the disclosed PLES as the probe, in combination with a separate, commercially available pump system. In some embodiments the pump system comprises a laser that is focused on the sample. In other embodiments the pump system applied s an electric or electromagnetic pulse across the sample. Synchronization of the electron pulses with the pump can be achieved by implementing phase-locked loop electronics between the pump system (.e.g. laser) and the EMMP to regulate the electromagnetic energy that is applied to the EMMP (e.g. RF phase or pulse timing). In embodiments, the timing jitter of the phase-lock loop is less than 10% of the minimum pulse width.

Potential applications of the present invention to SEM systems include low dose or time-structured dose modulation for beam-sensitive materials or chip inspection and metrology, ultrafast nanosecond or picosecond pump-probe applications, fast electron-beam-induced current (EBIC) for minority carrier lifetime in semiconductor chips, picosecond time-resolved photoluminescence, or single-electron-regime enhancements to spatial resolution. Future iterations may image ultrafast Kikuchi diffraction dynamics, enable improved rapid scanning capability for advanced sparse scanning algorithms, or cross over to related electron beam devices such as time-resolved small angle x-ray scattering or rapid-scan direct write electron beam lithography.

A first general aspect of the present invention is an Electro Magnetic Mechanical Pulser (“EMMP”) comprising an input configured to accept a continuous input electron beam traveling in an electron beam direction in an electron beam direction, and characterized by an electron energy that is equal to or less than 30 keV, a Low Energy Stripline kicker (“LES” kicker) located downstream of the input and having an internal passage through which the electron beam passes, each electron of the electron beam requiring an electron transit time te to traverse the internal passage, the LES kicker comprising at least one electromagnetic input proximate a first end of the LES and at least one corresponding impedance termination on an opposing second end of the LES, the impedance termination having an impedance that is matched to an impedance of the LES, the LES being configured to cause electromagnetic energy applied to the electromagnetic input to impose a transverse time-varying deflection on the electron beam according to at least one of a transverse time-varying electric field and a transverse time-varying magnetic field generated within the LES kicker by an electromagnetic traveling wave propagated through the LES kicker, and an output configured to allow electron pulses to emerge from the EMMP as an output stream of electron pulses having an electron pulse width and an electron pulse repetition rate. The EMMP is configured to cause the electron pulses width to be between 100 fs and 100 ns.

Embodiments further include a Chopping Collimating Aperture (“CCA”) located downstream of the LES kicker and configured to block the electron beam when its deflection exceeds a threshold maximum or minimum, thereby chopping the electron beam into the stream of electron pulses. In some of these embodiments the CCA can be translated to align an aperture thereof with the electron beam when its deflection is minimal. In any of these embodiments the CCA can include first and second CCA plates having aligned first and second apertures offset in the electron beam direction, the CCA being thereby configured to block the electron beam when it passes through the first aperture with significant deflection.

In any of the above embodiments, an impedance of each of the at least one impedance terminations can be 50 Ohms.

In any of the above embodiments, the LES can be configured to cause the electromagnetic traveling wave to traverse the LES parallel to the electron beam in the electron beam direction, or the LES can be configured to cause the electromagnetic traveling wave to traverse the LES parallel to the electron beam but opposite to the electron beam direction.

In any of the above embodiments, the electromagnetic energy can be RF energy, and a frequency of the RF wave can be tuned according to the electron transit time te and a length of the LES such that a phase slippage between the RF energy and the electron beam during the electron transit time is equal to 180 degrees. Some of these embodiments further include feedback electronics configured to monitor the phase slippage and to adjust at least one of the electron beam energy and the RF frequency to maintain the phase slippage substantially equal to 180 degrees. In any of these embodiments, an amplitude of the RF energy can be automatically adjusted by electronic feedback and/or computer control to maintain a displacement of the beam constant when an energy of the electron beam is changed. In any of these embodiments the LES kicker can include opposing first and second elongated elements separated by a gap therebetween, the at least one electromagnetic input can include first and second electromagnetic inputs applied respectively to the first and second elongated elements at the first end of the LES, the at least one impedance termination can include first and second impedance terminations applied respectively to the first and second elongated elements at the second end of the LES, and the LES kicker can be configured for simultaneous application of the RF energy to the first and second electromagnetic inputs with equal amplitudes and opposite phases.

Or the electromagnetic energy can be a train of voltage pulses. In some of these embodiments pulse widths of the voltage pulses are between 1 ps and 100 ns. In any of these embodiments, the LES kicker can include opposing first and second elongated elements separated by a gap therebetween, the at least one electromagnetic input can include a first electromagnetic input applied to the first elongated elements at the first end of the LES, the at least one impedance termination can include a first impedance termination applied to the first elongated element at the second end of the LES, the LES kicker can include a bias input applied to the second elongated element, and the LES kicker can be configured for simultaneous application of the voltage pulses to the first electromagnetic input and of a DC bias voltage to the bias input, the DC bias and voltage pulses being equal and opposite in amplitude, such that no electromagnetic field is applied to the electron beam during the voltage pulses, while a DC bias field is applied to the electron beam between the voltage pulses.

Or, the LES kicker can include opposing first and second elongated elements separated by a gap therebetween, the at least one electromagnetic input can include first and second electromagnetic inputs applied respectively to the first and second elongated elements at the first end of the LES, the at least one impedance termination can include first and second impedance terminations applied respectively to the first and second elongated elements at the second end of the LES, and the LES kicker can be configured for simultaneous application of the voltage pulses to the first and second electromagnetic inputs as overlapping but offset voltage pulses having opposing amplitudes, such that electron pulses are generated only during simultaneous application of the voltage pulses to both of the first and second electromagnetic inputs.

In any of these embodiments, a pulse repetition rate of the train of voltage pulses can be adjustable up to a pulse repetition rate of 1 GHz.

Any of the above embodiments can further include a synchronization system configured to maintain a synchronization between application of the electromagnetic energy to the electromagnetic input and application of an external probe pulse applied to a sample as a pump signal. In some of these embodiments, a relative stochastic or systematic jitter of the synchronization is less than 10% of a width of the probe pulse. In any of these embodiments, the synchronization system can perform phase-locked-loop (PLL) timing alignment of the electromagnetic energy with the external probe pulse. In any of these embodiments, the probe pulse can be a mode-locked laser pulse, or an electromagnetic pulse. In any of these embodiments a pump signal can be transmitted in a phase-locked delay line from an output of the EMMP to a sample holder.

A second general aspect of the present invention is a method of producing a pulsed electron beam. The method includes providing an EMMP according to the first general embodiment, wherein the electromagnetic energy is RF energy, causing a beam of electrons to pass through the LES of the EMMP, according to the electron transit time te and a length of the LES, tuning a frequency of the RF energy such that a phase slippage between the RF energy and the electrons of the electron beam during te is equal to 180 degrees, and positioning the CCA of the EMMP such that the electron beam is able to pass through the CCA only when a phase of the RF energy results in displacement of the electron beam without substantial transverse momentum.

A third general aspect of the present invention is a method of producing a pulsed electron beam, the method comprising providing an EMMP according to the first general aspect, causing a beam of electrons to pass through the LES of the EMMP, applying a train of voltage pulses to the electromagnetic input, and applying a DC bias voltage to the bias input, the DC bias and voltage pulses being equal and opposite in amplitude, such that the electron beam is able to pass through the EMMP only during the voltage pulses.

A fourth general aspect of the present invention is a method of producing a pulsed electron beam. The method includes providing an EMMP according to the first general aspect, causing a beam of electrons to pass through the LES of the EMMP, and simultaneously applying a first train of voltage pulses to the first electromagnetic input and a second train of voltage pulses to the second electromagnetic input, wherein the voltage pulses of the first train are offset from the voltage pulses of the second train, but partially overlap the voltage pulses of the second train, the voltages pulses of the first and second trains having opposing amplitudes, such that the electron beam is able to pass through the EMMP only during simultaneous application of the voltage pulses of the first and second trains.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1A is a conceptual diagram that illustrates the fundamental concepts underlying the EMMP approach of the prior art;

FIG. 1B is a conceptual diagram that depicts an EMMP system according to the Prior Art that includes a demodulating section comprising a demodulating kicker and three magnetic quadrupoles;

FIG. 2A illustrates an RF LES kicker according to an embodiment that implements forward RF propagation;

FIG. 2B illustrates an RF LES kicker according to an embodiment that implements reverse RF propagation;

FIG. 3A illustrates the RF waveform that is experienced by an electron transiting the LES which enters when the RF amplitude is at its maximum;

FIG. 3B illustrates the RF waveform that is experienced by an electron transiting the LES which enters when the RF amplitude is at its minimum;

FIG. 3C illustrates the displacement paths of the electrons that result from the RF waveforms of FIGS. 3A and 3B, such that the electron beam exiting the LES has substantially no divergence, and showing a moveable CCA having an aperture positioned to select one of these displacement paths;

FIG. 3D illustrates an LES having two apertures separated in the beam direction that select the displaced electrons passing through that have zero divergence, while rejecting electrons that pass through the first aperture at a divergent angle that is substantially non-zero;

FIG. 4A illustrates a Pulse LES kicker according to an embodiment that implements forward voltage pulse propagation with DC bias;

FIG. 4B illustrates a Pulse LES kicker according to an embodiment that implements reverse voltage pulse propagation with DC bias;

FIG. 5A illustrates application of offset but overlapping positive and negative voltage pulses to a PLES;

FIG. 5B illustrates a train of narrow electron pulses resulting from the voltage pulses of FIG. 5A;

FIG. 6 illustrates an LES kicker that contains a dielectric;

FIG. 7 illustrates an LES kicker that implements a traveling wave metallic comb structure in lieu of parallel flat plates; and

FIG. 8 illustrates an SEM system that has been retrofitted to include an LES pulser according to the present invention in lieu of a traditional electrostatic blanker, and wherein the SEM system is configured with synchronization of a laser pump and an LES-pulsed electron beam probe.

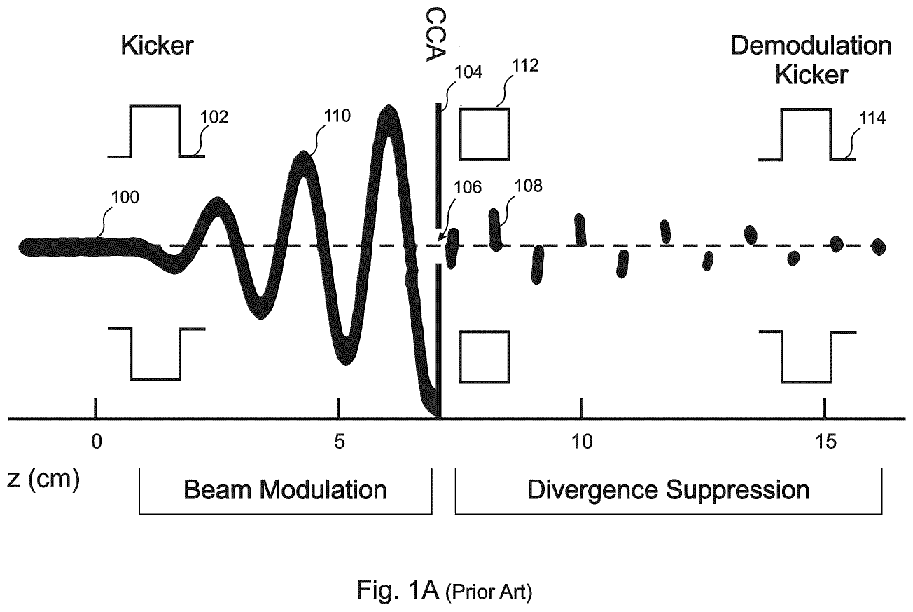

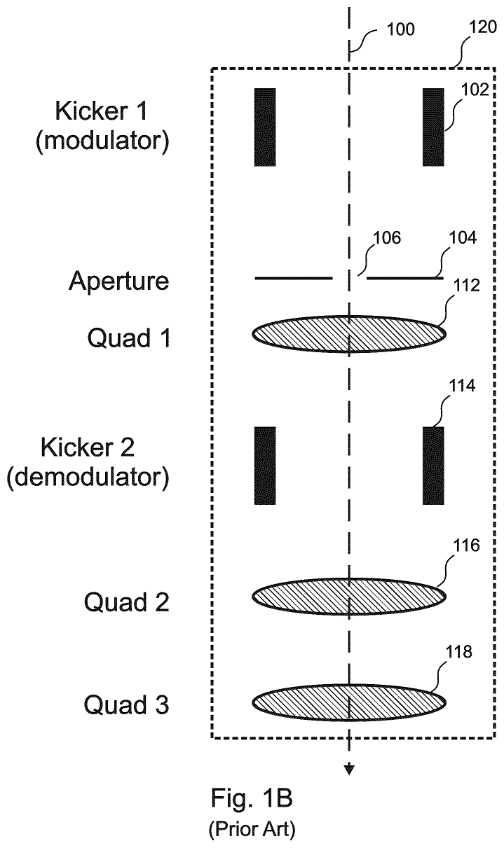

### DETAILED DESCRIPTION

The present invention is an ultrafast electrostatic EMMP deflector that is capable of deflecting electron beams having energies from 1-30 keV to produce pulsed electron beams having pulse repetition rates up to 20 GHz with little if any divergence. In embodiments, the disclosed electrostatic deflector, also referred to as a “low energy stripline” or LES kicker, is a single compact module that can be included in an SEM column, thereby enabling retrofit to existing SEM designs.

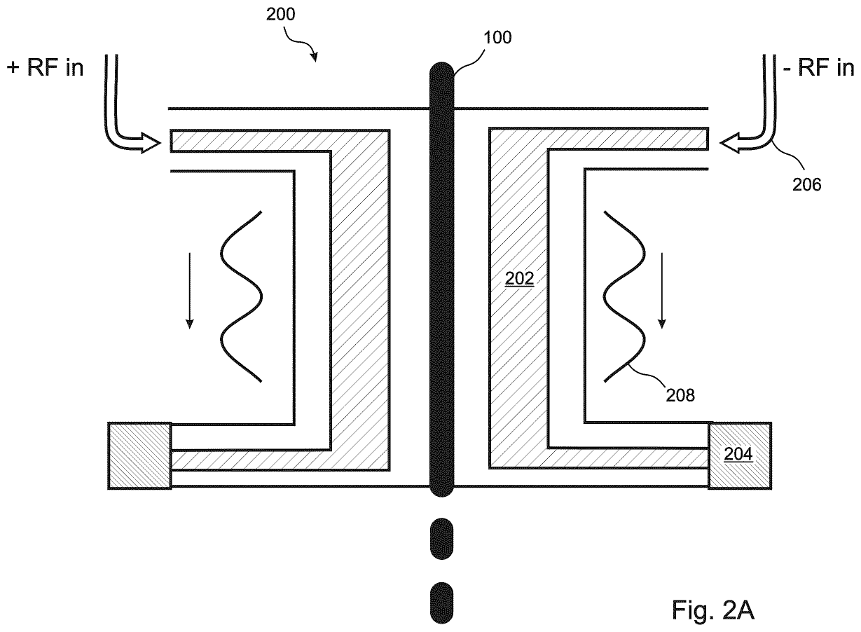

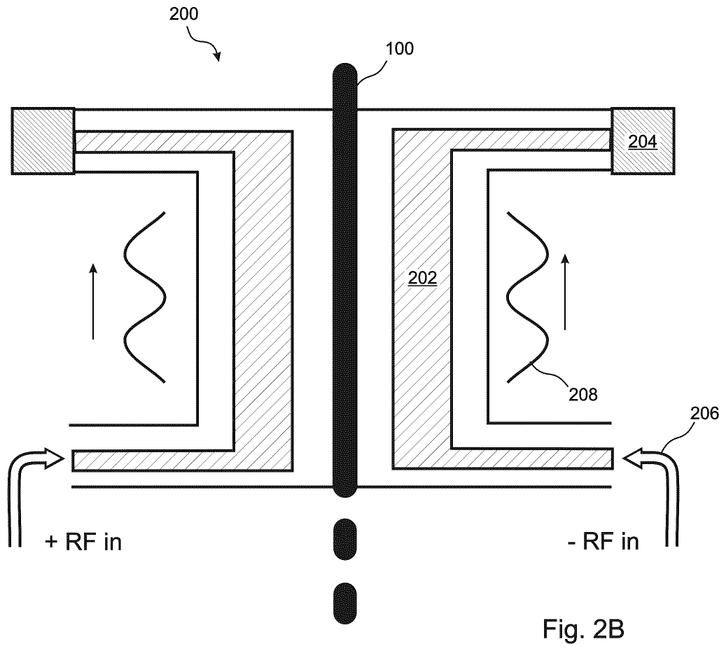

With reference to FIG. 2A, the disclosed LES kicker 200 includes a stripline 202 with at least one termination impedance (such as 50 ohms) 204 that matches the impendence of the stripline 202, thereby providing an ultra-high bandwidth stripline 200 that can propagate pure traveling wave electromagnetic energy over a frequency range from DC to nearly 20 GHz, which corresponds to less than 100 ps rise time. In the embodiment of FIG. 2A, the LES kicker comprises two flat metallic parallel slabs 202 that are fed by two coaxial ports 206 with signals 208 having a relative phase difference of 180 degrees (differential input). The CCA 104 (if included) of the LES pulser can have an aperture 106 of between 1 mm and 70 micrometers.

Rather than attempting to avoid RF phase slipping or limiting the interaction time between the electrons 100 and RF 208 traveling through the LES kicker 200, the disclosed invention implements either of two alternatives. The first approach, illustrated in FIGS. 2A and 2B, is referred to herein as RF LES. According to the RF LES approach, radio frequency energy is applied to the LES kicker 200 at a frequency tuned such that the total phase slippage during the transit time tₑ of each electron through the stripline 202 is 180 degrees.

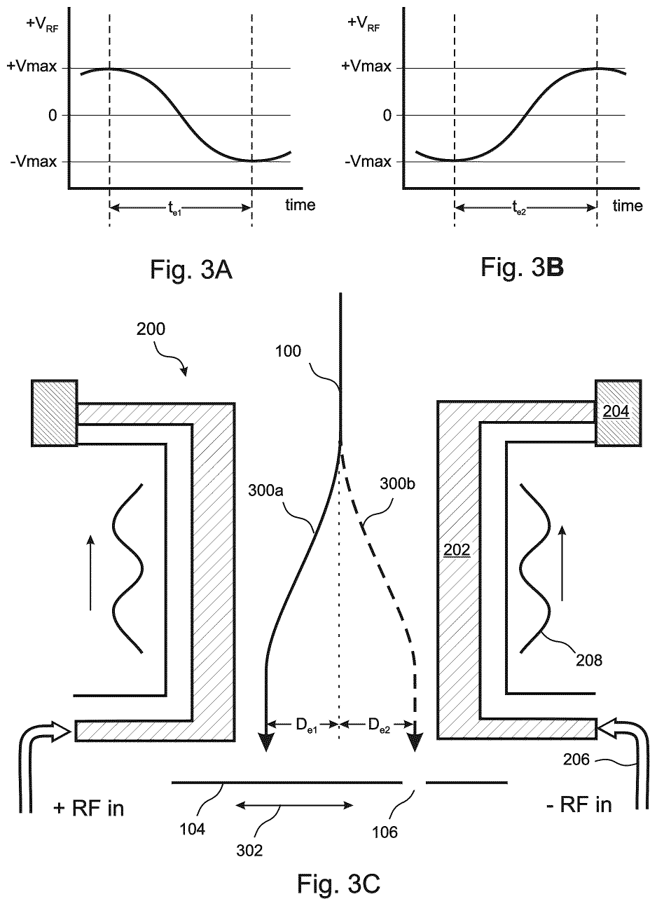

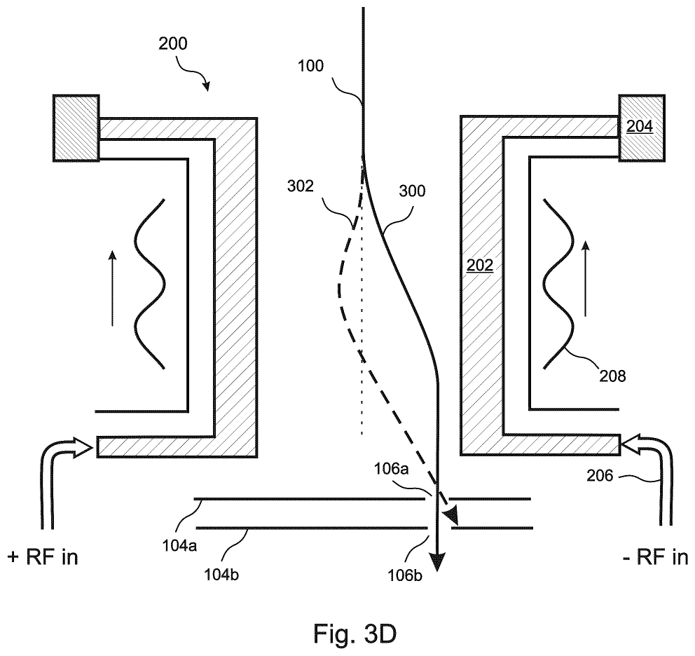

With reference to FIGS. 3A through 3C, when an electron enters the LES kicker 200, the electron will be deflected, and will not pass through the CCA 104, unless it enters the LES kicker at a moment when the RF voltage is at its maximum (FIG. 3A) or minimum (FIG. 3B) value, i.e. Vmax or −Vmax, in which case the electron will be displaced, and will pass through the CCA. Accordingly, the electrons that pass through the CCA and contribute to the pulsed output beam are displaced but have negligible transverse momentum, and the divergence of the output beam is minimized or eliminated. As a result, in embodiments it is not necessary to include downstream dispersion-suppressing elements 112, 114. In the embodiments of FIG. 3C, a transversely moveable CCA 104 is implemented, thereby enabling the position of the aperture 106 to be precisely placed in a location where only the beam 300b with substantially no transverse momentum can pass through.

In the embodiment of FIG. 3C, the aperture 106 of the CCA 104 is small enough to allow the beam 300b to pass through when it is displaced in one direction, while blocking the beam 300a when it is displaced in the other direction. The required RF frequency in this approach is determined by the energy (and hence the velocity) of the electron beam 100 and the length of the stripline 202. Embodiments employ feedback circuits that stabilize and maintain the phase slippage at 180 degrees and/or the amplitude of the beam displacement fixed as the beam energy is varied during normal SEM operation.

With reference to FIG. 3D, in addition to the displaced beam 300 that will pass through the aperture 106 of the CCA 104 without transverse momentum, a second, “return sweep” beam 302 will also be generated that will impact the aperture 106 with transverse momentum. In the embodiment of FIG. 3D, a two-slit “double CCA 104a, 104b with corresponding apertures 106a, 106b is implemented that blocks the return sweep beam 302 while allowing the displaced beam 300 to pass through. In similar embodiments, for example when an RF LES is implemented in an SEM column, the return sweep beam is blocked by a downstream aperture that is already present in the SEM design and easily removes the divergent return sweep beam, leaving only the displaced beam with zero transverse velocity.

The electron pulse repetition rate for RF LES embodiments is equal to the RF frequency, and can be as high as 20 GHz.

With reference again to FIGS. 2A and 2B, the LES kicker 200 of FIG. 2A is configured to cause the electromagnetic energy to travel through the stripline in the same direction as the electrons (forward propagation). In the embodiment of FIG. 2B, the LES kicker 200 is configured to cause the electromagnetic energy to travel in the opposite direction as the electrons (reverse propagation). Reverse RF propagation increases the phase slippage per unit length of the LES stripline 202 at a given RF frequency. This reverse propagation approach enables the length of the LES 202 to be reduced as compared to a forward propagating slippage scheme, thereby making the LES EMMP 200 more compact for a given beam energy and RF frequency. The same reverse propagation approach alternatively allows a the RF frequency, and therefore the pulse repetition rate, to be increased for a given energy of the electron beam 100 and length of the LES stripline 202.

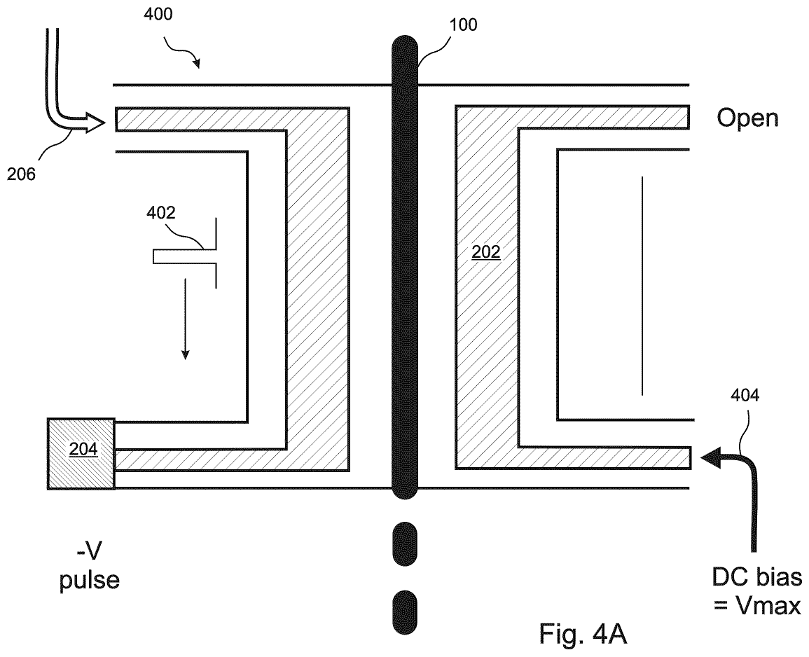

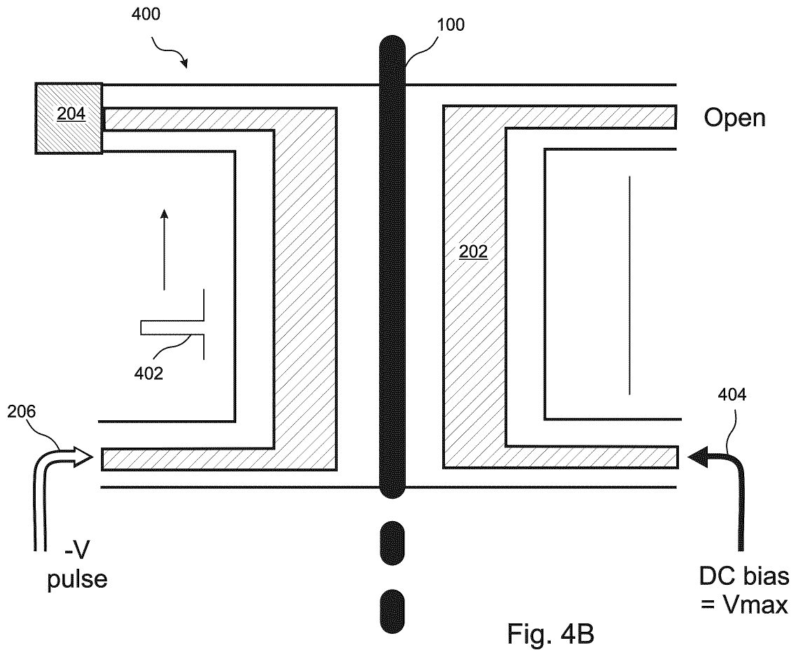

With reference to FIGS. 4A and 4B, in the second approach, referred to herein as Pulse LES or PLES, the PLES stripline 202 is driven by a series of unipolar, substantially square voltage pulses 402 produced by a voltage pulse generator (not shown). In embodiments, the voltage pulse generator is able to produce voltage pulses having durations shorter than what can be used to drive prior art electrostatic deflector plates, if the voltage pulse generator is impedance matched to the PLES stripline. In the embodiments of FIGS. 4A and 4B, the voltage pulses 402 are directed to one of the slabs 202 of the PLES 400, which is impedance matched 204, while a DC bias 404 that is equal and opposite to the maximum amplitude of the voltage pulses is applied to the other slab 202 of the PLES 202. As a result, electrons in the beam are deflected, and do not pass through the CCA, except during the voltage pulses 402, when the net field in the PLES stripline 202 is zero.

With proper PLES impedance matching 204, settling times of less than 80 ps between the on and off states of the voltage pulses 402 in the PLES can be achieved, corresponding to electron pulse durations (width) of less than 10 ps, with up to 400 MHz pulse repetition frequency. Embodiments are able to provide electron pulses having electron pulse widths between 100 fs and 100 ns.

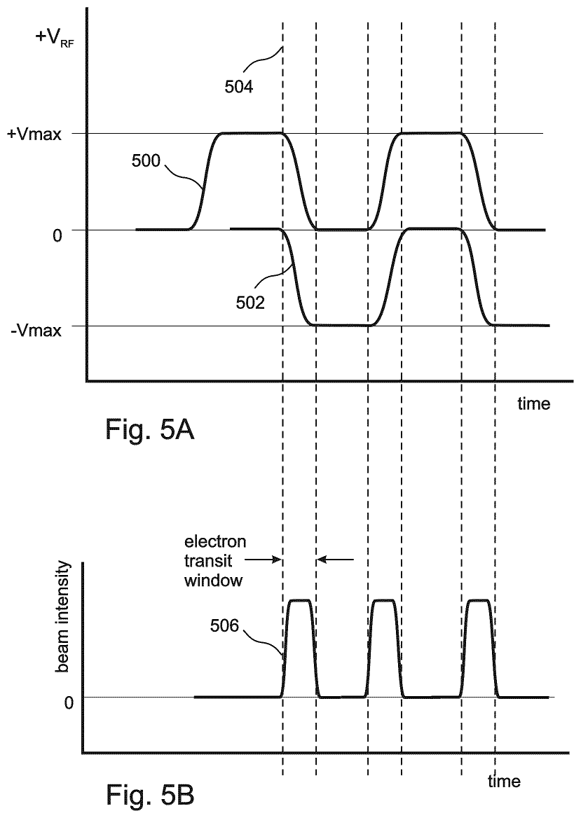

According to the PLES approach, the electron pulse widths and pulse repetition rates in the output beam are determined by the lengths and repetition rate of the voltage pulses 402. Accordingly, the electron beam 100 is deflected and blocked by a subsequent limiting aperture when there is no voltage pulse applied 402 (only DC bias), and is transmitted through the PLES kicker 202 only when a voltage pulse 402 is present. In some embodiments, the disclosed pulser 200 does not include a CCA 104, and beam cutoff is achieved instead at existing downstream microscope apertures. In other embodiments, a CCA 104 is included to ensure collimation of the beam 100, and to block the beam 100 between the voltage pulses. In some embodiments (described in more detail below with reference to FIGS. 5A and 5B), the CCA aperture 106 can also serve to allow the beam 100 to pass through during the rise and fall times of the voltage pulses 402, thereby shortening the durations of the electron beam pulses.

Unlike RF energy 208, which transitions sinusoidally between positive and negative voltages, the nearly square voltage pulses 402 alternate between a maximum amplitude and zero. Adjustment of the pulsing rate according to the electron transit time tₑ through the stripline 202 is therefore not required. The only time-dependent beam divergence that arises in PLES embodiments such as FIGS. 4A and 4B occurs during the rising and falling edges of the voltage pulses 402. For this reason, the electron deflection efficiency is unavoidably beam-energy-dependent at the rising or falling edges of the voltage pulses 402. However, with reference to FIG. 3B, these rising and falling edges can be minimized by reverse propagation of the voltage pulses 402 through the PLES stripline 202. A flat-top pulse 402 that is long compared to its rise and fall times guarantees most of the beam will have the desired minimum divergence.

FIGS. 5A and 5B illustrate a PLES embodiment that provides extremely narrow electron pulses by applying both positive 500 and negative 502 voltage pulses to the PLES 400 that overlap, but are opposite in sign from each other. The positive voltage pulses 500 are applied to one of the PLES slabs 202, while the negative pulses 502 are applied to the other of the PLES slabs 202, and both of the slabs 202 are impedance terminated 204, in a manner similar to FIGS. 2A and 2B. According to this approach, electrons are only able to pass through the CCA during narrow electron transit windows 504 during the overlap between the voltage pulses 500, 502 when the net deflection force is substantially zero. The result is a train of electron pulses 506 having widths that are determined by the degree of overlap between the voltage pulses 500, 502, and the rise and fall times of the voltage pulses 500, 502.

In similar embodiments, the CCA aperture 106 blocks the beam 100 except during the rise and fall times of the voltage pulses 500, for example if the applied DC bias is set to half of the voltage pulse amplitude, thereby substantially shortening the durations of the electron beam pulses.

Accordingly, PLES embodiments allow virtually any desired combination of beam energy, electron pulse width, and pulse repetition rate. This is particularly important for critical-dimension SEM in chip fabs, which usually operate at beam energies well below 30 keV. In various Pulse LES embodiments, electron pulse repetition rates of up to 1 GHz can be achieved.

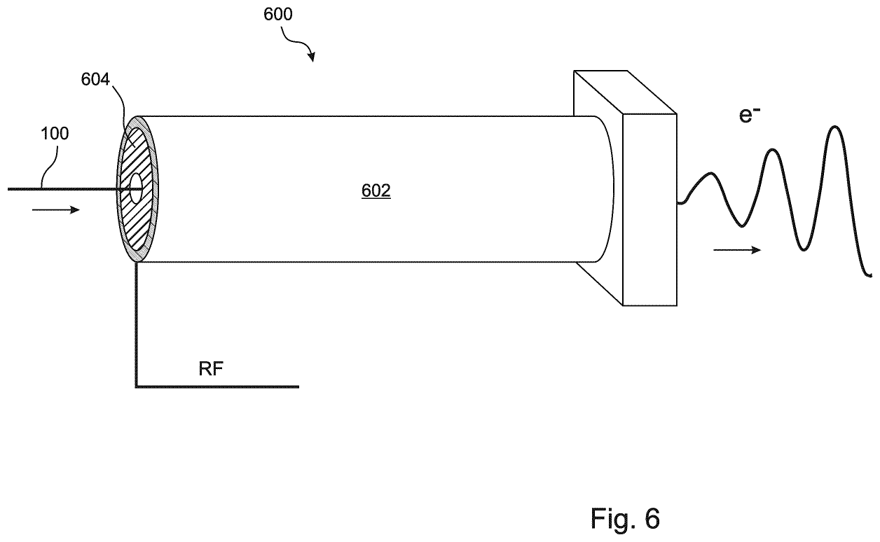

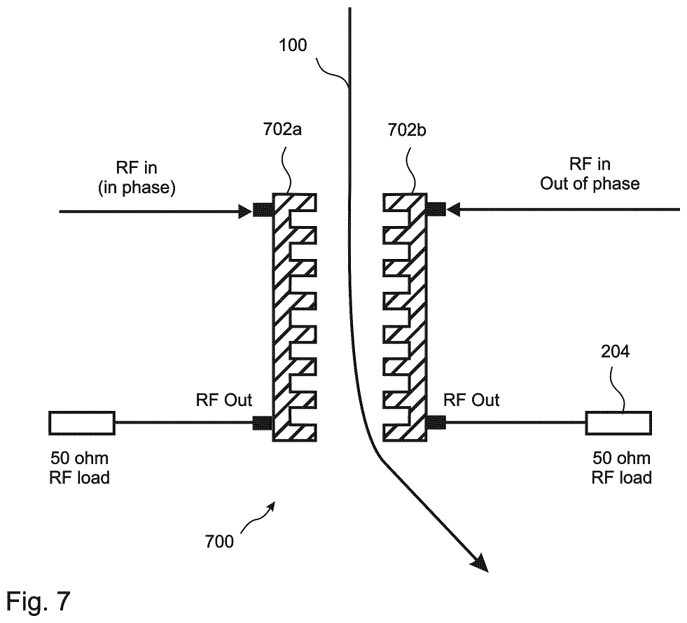

In the embodiments of FIGS. 2A-4B, the LES stripline 202 comprises a pair of impedance terminated parallel plates separated by a vacuum. In the embodiment of FIG. 6 the LES 600 includes a stripline 602 that contains a dielectric 604. Similarly, in the embodiment of FIG. 7, the stripline 702a, 702b (collectively 702) is not formed from parallel plates 202, but is formed instead as a pair of metallic combs 702a, 702b. Both of these approaches 602, 702 reduce the phase velocity of the RF or electrostatic pulses in the LES 602, 702, thereby increasing the required RF frequency and/or extending the required length of the LES kickers 600, 700 to provide a stronger deflection of the beam 100.

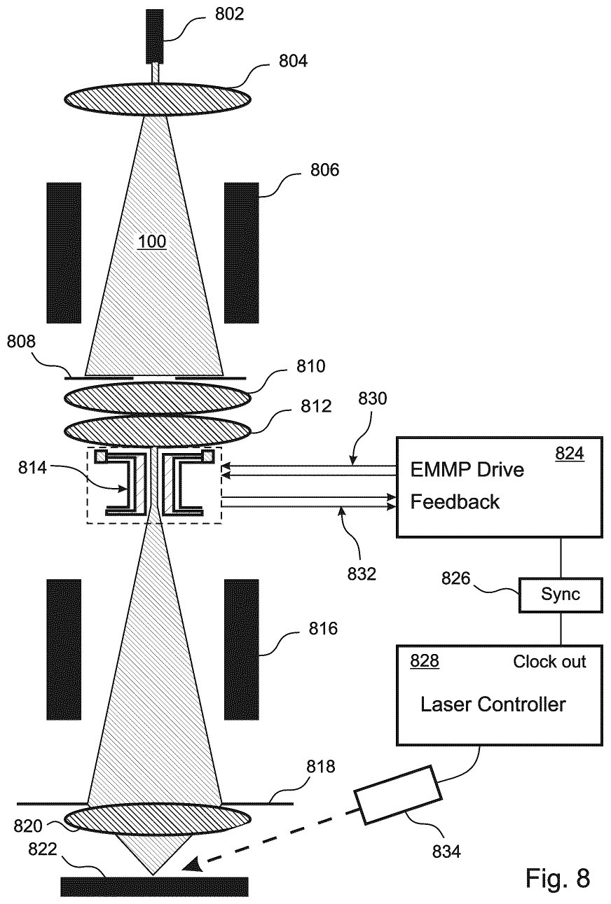

Due to the compactness that can be achieve by the disclosed EMMP, embodiments can be retrofit to existing SEM designs, or even to existing SEM apparatus. In one embodiment, the EMMP is inserted just below the gun gate valve. In another, the EMMP is inserted further downstream. FIG. 8 illustrates a retrofitted SEM system in which an embodiment of the disclosed EMMP 814 has been installed in place of a prior art electrostatic blanker, with substantially all other elements of the SEM system remaining unchanged. The illustrated SEM system includes a Schottky electron beam source 802, a condenser lens 804, and a pair of gun shift/tilt coils 806. The pulsed electron beam 100 then passes through a 70 um current limiting aperture 808, a second condenser lens 810, and a deceleration lens 812. At this point, the continuous electron beam 100 is chopped into a pulsed beam by an LES embodiment 814 of the present invention.

After being chopped into pulses, the beam 100 passes through a pair of scanning coils 816, and then through a blanking aperture 818 and an electron objective with 70 um 820. Finally, the focused, pulsed beam 100 impinges on the sample 822.

In similar embodiments (not shown), the disclosed EMMP 814 is inserted below the SEM electron beam source 802, accelerator, and gun shift/tilt coils 806, but above the optical elements including condenser lenses 804, deceleration lens 812, and scanning coils 816.

The embodiment of FIG. 8 is configured for stroboscopic laser pump-probe imaging using the PLES 814 as the probe, and further comprises a separate, commercially available laser 834 focused on the sample 822 as a pump. In similar embodiments, the pump is an electric or electromagnetic pulse applied across the sample 822. Synchronization in the embodiment of FIG. 8 is achieved by implementing synchronizing phase-locked loop (PLL) electronics 826 between the laser controller 828 and the EMMP drive 824 that applies electromagnetic energy 830 to the EMMP 814. In the illustrated embodiment, the EMMP 814 is configured to provide timing feedback 832 to the EMMP drive 824, and ultimately to the PLL electronics 826. In embodiments, the timing jitter of the phase-lock loop will be <10% of the minimum pulse width.

Potential applications of the present invention to SEM systems include low dose or time-structured dose modulation for beam-sensitive materials or chip inspection and metrology, ultrafast nanosecond or picosecond pump-probe applications, fast electron-beam-induced current (EBIC) for minority carrier lifetime in semiconductor chips, picosecond time-resolved photoluminescence, or single-electron-regime enhancements to spatial resolution. Future iterations may image ultrafast Kikuchi diffraction dynamics, enable improved rapid scanning capability for advanced sparse scanning algorithms, or cross over to related electron beam devices such as time-resolved small angle x-ray scattering or rapid-scan direct write electron beam lithography.

The foregoing description of the embodiments of the invention has been presented for the purposes of illustration and description. Each and every page of this submission, and all contents thereon, however characterized, identified, or numbered, is considered a substantive part of this application for all purposes, irrespective of form or placement within the application.

This specification is not intended to be exhaustive. Although the present application is shown in a limited number of forms, the scope of the invention is not limited to just these forms, but is amenable to various changes and modifications without departing from the spirit thereof. One or ordinary skill in the art should appreciate after learning the teachings related to the claimed subject matter contained in the foregoing description that many modifications and variations are possible in light of this disclosure. Accordingly, the claimed subject matter includes any combination of the above-described elements in all possible variations thereof, unless otherwise indicated herein or otherwise clearly contradicted by context. In particular, the limitations presented in dependent claims below can be combined with their corresponding independent claims in any number and in any order without departing from the scope of this disclosure, unless the dependent claims are logically incompatible with each other.

I claim:

1. An Electro Magnetic Mechanical Pulser (“EMMP”) comprising:
an input configured to accept a continuous input electron beam traveling in an electron beam direction in an electron beam direction, and characterized by an electron energy that is equal to or less than 30 keV;
a Low Energy Stripline kicker (“LES” kicker) located downstream of the input and having an internal passage through which the electron beam passes, each electron of the electron beam requiring an electron transit time tₑ to traverse the internal passage, the LES kicker comprising at least one electromagnetic input proximate a first end of the LES and at least one corresponding impedance termination on an opposing second end of the LES, the impedance termination having an impedance that is matched to an impedance of the LES, the LES being configured to cause electromagnetic energy applied to the electromagnetic input to impose a transverse time-varying deflection on the electron beam according to at least one of a transverse time-varying electric field and a transverse time-varying magnetic field generated within the LES kicker by an electromagnetic traveling wave propagated through the LES kicker; and
an output configured to allow electron pulses to emerge from the EMMP as an output stream of electron pulses having an electron pulse width and an electron pulse repetition rate;
wherein the EMMP is configured to cause the electron pulses width to be between 100 fs and 100 ns.

2. The EMMP of claim 1, further comprising a Chopping Collimating Aperture (“CCA”) located downstream of the LES kicker and configured to block the electron beam when its deflection exceeds a threshold maximum or minimum, thereby chopping the electron beam into the stream of electron pulses.

3. The EMMP of claim 2, wherein the CCA can be translated to align an aperture thereof with the electron beam when its deflection is minimal.

4. The EMMP of claim 2, wherein the CCA comprises first and second CCA plates having aligned first and second apertures offset in the electron beam direction, the CCA being thereby configured to block the electron beam when it passes through the first aperture with significant deflection.

5. The EMMP of claim 1, wherein the LES is configured to cause the electromagnetic traveling wave to traverse the LES parallel to the electron beam in the electron beam direction, or wherein the LES is configured to cause the electromagnetic traveling wave to traverse the LES parallel to the electron beam but opposite to the electron beam direction.

6. The EMMP of claim 1, wherein the electromagnetic energy is RF energy, and wherein a frequency of the RF wave is tuned according to the electron transit time tₑ and a length of the LES such that a phase slippage between the RF energy and the electron beam during the electron transit time is equal to 180 degrees.

7. The EMMP of claim 6, further comprising feedback electronics configured to monitor the phase slippage and to adjust at least one of the electron beam energy and the RF frequency to maintain the phase slippage substantially equal to 180 degrees.

8. The EMMP of claim 6, wherein an amplitude of the RF energy is automatically adjusted by electronic feedback and/or computer control to maintain a displacement of the beam constant when an energy of the electron beam is changed.

9. The EMMP of claim 6, wherein:
the LES kicker comprises opposing first and second elongated elements separated by a gap therebetween;
the at least one electromagnetic input comprises first and second electromagnetic inputs applied respectively to the first and second elongated elements at the first end of the LES;
the at least one impedance termination comprises first and second impedance terminations applied respectively to the first and second elongated elements at the second end of the LES; and
the LES kicker is configured for simultaneous application of the RF energy to the first and second electromagnetic inputs with equal amplitudes and opposite phases.

10. The EMMP of claim 9, wherein the electromagnetic energy is a train of voltage pulses.

11. The EMMP of claim 9, wherein:
the LES kicker comprises opposing first and second elongated elements separated by a gap therebetween;
the at least one electromagnetic input comprises a first electromagnetic input applied to the first elongated elements at the first end of the LES;
the at least one impedance termination comprises a first impedance termination applied to the first elongated element at the second end of the LES;
the LES kicker comprises a bias input applied to the second elongated element; and
the LES kicker is configured for simultaneous application of the voltage pulses to the first electromagnetic input and of a DC bias voltage to the bias input, the DC bias and voltage pulses being equal and opposite in amplitude, such that no electromagnetic field is applied to the electron beam during the voltage pulses, while a DC bias field is applied to the electron beam between the voltage pulses.

12. The EMMP of claim 9, wherein:
the LES kicker comprises opposing first and second elongated elements separated by a gap therebetween;
the at least one electromagnetic input comprises first and second electromagnetic inputs applied respectively to the first and second elongated elements at the first end of the LES;
the at least one impedance termination comprises first and second impedance terminations applied respectively to the first and second elongated elements at the second end of the LES; and
the LES kicker is configured for simultaneous application of the voltage pulses to the first and second electromagnetic inputs as overlapping but offset voltage pulses having opposing amplitudes, such that electron pulses are generated only during simultaneous application of the voltage pulses to both of the first and second electromagnetic inputs.

13. The EMMP of claim 9, wherein a pulse repetition rate of the train of voltage pulses is adjustable up to a pulse repetition rate of 1 GHz.

14. The EMMP of claim 1, further comprising a synchronization system configured to maintain a synchronization between application of the electromagnetic energy to the electromagnetic input and application of an external probe pulse applied to a sample as a pump signal.

15. The EMMP of claim 14, wherein the synchronization system performs phase-locked-loop (PLL) timing alignment of the electromagnetic energy with the external probe pulse.

16. The EMMP of claim 14, wherein the probe pulse is a mode-locked laser pulse or an electromagnetic pulse.

17. The EMMP of claim 14, wherein a pump signal is transmitted in a phase-locked delay line from an output of the EMMP to a sample holder.

18. A method of producing a pulsed electron beam, the method comprising:
providing an EMMP according to claim 1, wherein the electromagnetic energy is RF energy;
causing a beam of electrons to pass through the LES of the EMMP;
according to the electron transit time tₑ and a length of the LES, tuning a frequency of the RF energy such that a phase slippage between the RF energy and the electrons of the electron beam during tₑ is equal to 180 degrees; and
positioning the CCA of the EMMP such that the electron beam is able to pass through the CCA only when a phase of the RF energy results in displacement of the electron beam without substantial transverse momentum.

19. A method of producing a pulsed electron beam, the method comprising:
providing an EMMP according to claim 11;
causing a beam of electrons to pass through the LES of the EMMP;
applying a train of voltage pulses to the electromagnetic input; and
applying a DC bias voltage to the bias input, the DC bias and voltage pulses being equal and opposite in amplitude, such that the electron beam is able to pass through the EMMP only during the voltage pulses.

20. A method of producing a pulsed electron beam, the method comprising:
providing an EMMP according to claim 12;
causing a beam of electrons to pass through the LES of the EMMP; and
simultaneously applying a first train of voltage pulses to the first electromagnetic input and a second train of voltage pulses to the second electromagnetic input, wherein the voltage pulses of the first train are offset from the voltage pulses of the second train, but partially overlap the voltage pulses of the second train, the voltages pulses of the first and second trains having opposing amplitudes, such that the electron beam is able to pass through the EMMP only during simultaneous application of the voltage pulses of the first and second trains.
